(19) United States
(12) Patent Application Publication
(10) Pub. No.: US 2026/0259257 A1
(43) Pub. Date: Sep. 3, 2026

(54) TEST METHOD, CORRECTION AMOUNT CALCULATION METHOD, AND TEST DEVICE

(71) Applicant: Tokyo Electron Limited, Tokyo (JP)

(72) Inventor: Shinjiro WATANABE, Yamanashi (JP)

(21) Appl. No.: 18/713,456

(22) PCT Filed: Nov. 28, 2022
(86) PCT No.: PCT/JP2022/043737

§ 371 Date: May 24, 2024

(30) Foreign Application Priority Data
Dec. 8, 2021 (JP) 2021-199314
Aug. 3, 2022 (JP) 2022-124206

(51) Int. Cl. G01R 31/28

(52) U.S. Cl. CPC G01R 31/2891

(57) ABSTRACT

A test method includes a step of calculating a correction amount in a three-dimensional direction that is used when a mounting table on which a substrate is mounted is moved in the three-dimensional direction before an electrical test is performed; and a step of moving the mounting table based on the calculated correction amount in the three-dimensional direction when the electrical test is performed. The step of calculating the correction amount in the three-dimensional direction includes acquiring information on a contact state in which the plurality of probes are in contact with the substrate while the mounting table is raised, and calculating the correction amount in the three-dimensional direction based on the acquired information on the contact state.

### TECHNICAL FIELD

The present disclosure relates to a test method, a correction amount calculation method, and a test device.

### BACKGROUND

Patent Document 1 discloses a probe device (a test device) that includes a main chuck on which a wafer is mounted and that performs an electrical test of the wafer by moving the main chuck in a three-dimensional direction (the X direction, the Y direction, and the Z direction) and a θ direction.

In such a test device, a stage and a wafer are inclined due to a load applied from a probe of a probe card at the time of the overdrive in the electrical test of the wafer. Thus, the test device obtains a movement correction amount of the stage in the three-dimensional direction at the time of the overdrive based on information on the stage, information on the wafer, and information on the probe card, and performs a process of moving the stage in accordance with the movement correction amount.

### Related Art Document

### Patent Document

[Patent Document 1] Japanese Laid-open Patent Application Publication No. H11-30651

### SUMMARY OF THE INVENTION

### Problem to Be Solved by the Invention

The present disclosure provides a technique of enabling a probe and a substrate to be brought into contact with each other with high accuracy.

### Means for Solving the Problem

According to an aspect of the present disclosure, there is provided a test method of performing an electrical test by bringing a substrate into contact with a plurality of probes, and including a step of calculating a correction amount in a three-dimensional direction that is used when a mounting table on which a substrate is mounted is moved in the three-dimensional direction before an electrical test is performed; and a step of moving the mounting table based on the calculated correction amount in the three-dimensional direction when the electrical test is performed. The step of calculating the correction amount in the three-dimensional direction includes acquiring information on a contact state in which the plurality of probes are in contact with the substrate while the mounting table is raised, and calculating the correction amount in the three-dimensional direction based on the acquired information on the contact state.

### Effect of the Invention

According to one aspect of the present disclosure, a probe and a substrate can be brought into contact with each other with high accuracy.

### BRIEF DESCRIPTION OF THE DRAWINGS

FIG. 1 is a schematic longitudinal sectional view illustrating a test device according to a first embodiment.

FIG. 2A is a schematic side view illustrating an operation in a case where 3D contact correction is not performed when a stage is moved.

FIG. 2B is a schematic side view illustrating an operation in a case where the 3D contact correction is performed when the stage is moved.

FIG. 3 is a graph indicating a change in a contact state of a wafer with respect to a probe of a probe card when the stage is moved in the Z-axis direction.

FIG. 4 is a block diagram illustrating functional blocks for performing a correction amount calculation process and the 3D contact correction.

FIG. 5A is a flowchart illustrating a processing flow of a correction amount calculation process of a test method.

FIG. 5B is a flowchart illustrating a processing flow of a test process of the test method.

FIG. 6 is a schematic plan view illustrating a stage of a test device according to a second embodiment, and an explanatory diagram illustrating a correction amount in a three-dimensional direction of an area.

FIG. 7A is an explanatory diagram illustrating a division pattern of multiple areas A in a correction amount calculation process according to a first modified example.

FIG. 7B is an explanatory diagram illustrating a division pattern of multiple areas A in a correction amount calculation process according to a second modified example.

FIG. 7C is an explanatory diagram illustrating a division pattern of multiple areas A in a correction amount calculation process according to a third modified example.

FIG. 7D is an explanatory diagram illustrating a division pattern of multiple areas A in a correction amount calculation process according to a fourth modified example.

FIG. 8 is a flowchart illustrating a test method (a correction amount calculation method) according to the second embodiment.

FIG. 9 is a schematic longitudinal sectional view illustrating a test device according to a third embodiment.

FIG. 10 is a graph indicating a change in the number of probe marks with respect to each Z coordinate.

FIG. 11 is a flowchart of a correction amount calculation process according to the third embodiment.

### DESCRIPTION OF THE EMBODIMENTS

In the following, embodiments of the present disclosure will be described with reference to the drawings. In the drawings, the same components are denoted by the same reference symbols, and a duplicate description thereof may be omitted.

### First Embodiment

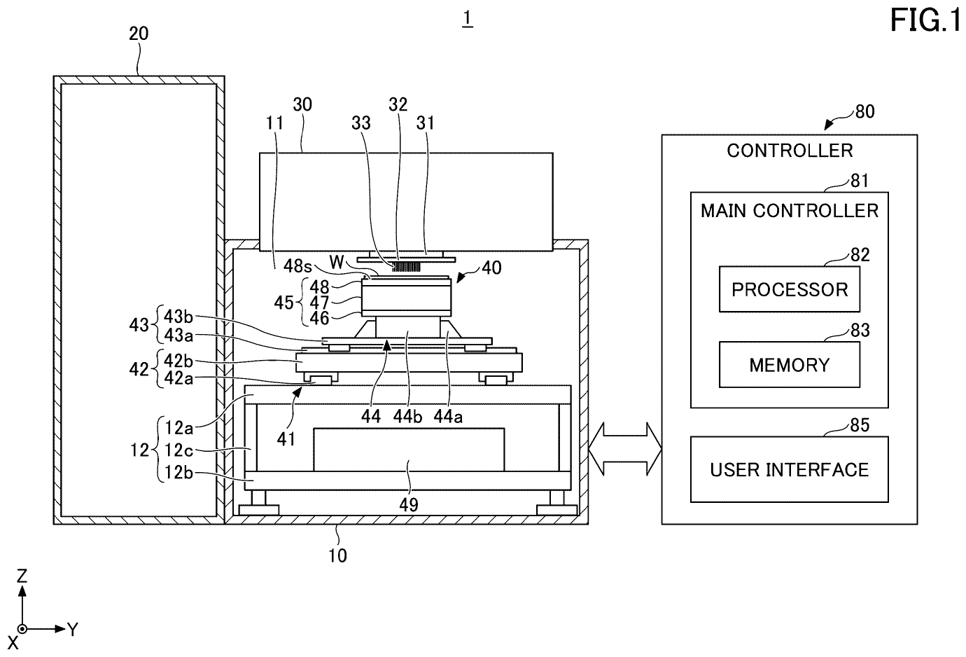

FIG. 1 is a schematic longitudinal sectional view illustrating a test device 1 according to a first embodiment. As illustrated in FIG. 1, the test device 1 according to the first embodiment is a device configured to test electrical characteristics of multiple semiconductor devices formed on a wafer (a substrate) W, which is an example of a device under test (DUT). Here, the substrate is not limited to the wafer W, and may be a carrier, a glass substrate, a single chip, an electronic circuit board, or the like, on which a semiconductor device is arranged.

The test device 1 includes a housing 10, a loader 20 disposed adjacent to the housing 10, and a tester 30 disposed on an upper side of the housing 10. The housing 10 is formed in a cuboid shape (a box shape) and has a test space 11 for testing the wafer W inside. The test device 1 accommodates a stage 40 on which the wafer W is mounted in the test space 11. Additionally, in the test device 1, the lower side of the tester 30 is disposed in the test space 11, and the tester 30 holds a probe card 32 via an interface 31.

The loader 20 takes out the wafer W from a FOUP (not illustrated), which is a transfer container, and mounts the wafer W on the stage 40 moved in the housing 10. Additionally, the loader 20 takes out the tested wafer W from the stage 40 and accommodates the wafer W in the FOUP.

The tester 30 includes, inside, a test board (not illustrated) for reproducing a circuit configuration of the wafer W on which a semiconductor device is provided, and is connected to a controller 80 of the test device 1. The test board determines whether the semiconductor device is acceptable or not based on a signal from the semiconductor device of the wafer W, and performs appropriate control. The tester 30 can reproduce circuit configurations of multiple types of the wafers W by switching multiple test boards, for example.

The probe card 32 held by the tester 30 includes a large number of probes 33 that are formed in a needle shape and that are disposed corresponding to pads and solder bumps of each of the semiconductor devices of the wafer W. In a test performed by the tester 30 according to the present embodiment, for example, the probe card 32 including several hundreds to several tens of thousands of probes 33 is applied. Each of the probes 33 supplies power from the tester 30 to the semiconductor device via the interface 31 or transmits a signal from the semiconductor device to the tester 30 via the interface 31 in a state of being in contact with the wafer W.

The test device 1 moves the wafer W held by the stage 40 relative to the probe card 32 connected to a test head of the tester 30, and causes the tester 30 to perform a test by pressing the probes 33 against the pads of the semiconductor device of the wafer W. The test device 1 tests all the semiconductor devices on the wafer W by sequentially repeating this test process while shifting the position of the test on the wafer W by the stage 40 moving in the X-axis direction, the Y-axis direction, and the Z-axis direction.

The stage 40 is movably provided in the housing 10 and transfers the wafer W or the probe card 32 in the test space 11. For example, the stage 40 can test the wafer W by transferring the wafer W from the loader 20 to a position facing the probe card 32 and raising the wafer W toward the probe card 32. After the test, the stage 40 lowers the tested wafer W from the probe card 32 and further transfers the wafer W toward the loader 20.

Specifically, the stage 40 includes a movement section 41 (an X-axis movement mechanism 42, a Y-axis movement mechanism 43, and a Z-axis movement mechanism 44) configured to move in the X-axis direction, the Y-axis direction, and the Z-axis direction, a mounting table 45, and a stage controller 49. Additionally, the housing 10 includes a frame structure 12 that supports the movement section 41, the mounting table 45, and the stage controller 49 of the stage 40 in two stages: upper and lower stages. For example, the frame structure 12 includes an upper base 12a that supports the movement section 41, a lower base 12b that supports the stage controller 49, and multiple support pillars 12c that are provided at four corners of the lower base 12b and support the upper base 12a.

The X-axis movement mechanism 42 of the movement section 41 includes multiple guide rails 42a fixed to the upper surface of the upper base 12a and extending along the X-axis direction, and an X-axis movable body 42b disposed between the guide rails 42a. The X-axis movable body 42b includes an X-axis actuator (a motor, a gear mechanism, or the like), which is not illustrated, therein, and the X-axis actuator is connected to the stage controller 49. The X-axis movable body 42b reciprocates in the X-axis direction based on the power supply from a motor driver, which is not illustrated, of the stage controller 49.

Similarly, the Y-axis movement mechanism 43 includes multiple guide rails 43a fixed to the upper surface of the X-axis movable body 42b and extending along the Y-axis direction, and a Y-axis movable body 43b disposed between the guide rails 43a. The Y-axis movable body 43b also includes a Y-axis actuator (a motor, a gear mechanism, or the like), which is not illustrated, therein, and the Y-axis actuator is connected to the stage controller 49. The Y-axis movable body 43b reciprocates in the Y-axis direction based on the power supply from the motor driver, which is not illustrated, of the stage controller 49.

The Z-axis movement mechanism 44 includes a fixed body 44a provided on the Y-axis movable body 43b and a Z-axis movable body 44b raised and lowered along the Z-axis direction relative to the fixed body 44a, and holds the mounting table 45 on the Z-axis movable body 44b. The Z-axis movable body 44b includes a Z-axis actuator (a motor, a gear mechanism, or the like), which is not illustrated, therein, and the Z-axis actuator is connected to the stage controller 49. The Z-axis movable body 44b is displaced in the Z-axis direction (the vertical direction) based on power supply from the motor driver, which is not illustrated, of the stage controller 49, and accordingly, the wafer W held by the mounting table 45 is raised and lowered. Here, the movement section 41 may have a configuration of rotating the mounting table 45 around an axis (in a θ direction) in addition to moving the mounting table 45 in the X-axis direction, the Y-axis direction, and the Z-axis direction.

The mounting table 45 is a device on which the wafer W is directly mounted, and is transferred by the movement section 41. The mounting table 45 includes a bottom plate 46 engaged with the Z-axis movement mechanism 44, a support block 47 stacked on the bottom plate 46, and a chuck top 48 stacked on the support block 47.

The support block 47 supports the chuck top 48 at an appropriate height position. Additionally, the test device 1 may include, inside the support block 47, a temperature control module (not illustrated) configured to control the temperature of the wafer W held by the mounting table 45. The chuck top 48 is formed in a substantially disk shape having a diameter greater than a diameter of the wafer W. The upper surface of the chuck top 48 forms a mounting surface 48s on which the wafer W is mounted.

Further, the mounting table 45 preferably includes an appropriate mechanism depending on a holding means for holding the wafer W on the mounting surface 48s. For example, when the wafer W is vacuum-suctioned, the holding means may have a suction passage for suction in the support block 47 or the chuck top 48, and a pipe and a suction pump connected to the suction passage may be provided at appropriate positions.

The stage controller 49 is connected to the controller 80 and controls the operation of the stage 40 based on an instruction from the controller 80. The stage controller 49 includes, for example, an integrated controller configured to control the operation of the entire stage 40, a PLC or a motor driver configured to control the operation of the movement section 41, an illumination controller, a power supply unit, and the like (none of which are illustrated).

The controller 80 of the test device 1 includes a main controller 81 configured to control the entire test device 1 and a user interface 85 connected to the main controller 81. The main controller 81 is configured by a computer, a control circuit board, and the like.

For example, the main controller 81 includes a processor 82, a memory 83, an input/output interface, and an electronic circuit, which are not illustrated. The processor 82 is one of or a combination of a CPU, an ASIC, an FPGA, a circuit including multiple discrete semiconductors, and the like. The memory 83 includes a volatile memory or a non-volatile memory (for example, a compact disc, a DVD, a hard disk drive, a flash memory, or the like), and stores a program for operating the test device 1 and a recipe in which test contents are described.

A keyboard with which a user performs an operation of inputting a command or the like, and a display that visualizes and displays an operation state of the test device 1 can be applied to the user interface 85. A device such as a touch panel, a mouse, a microphone, or a speaker may be applied to the user interface 85.

The controller 80 controls each component of the test device 1 to test the wafer W. When the wafer W is tested, the test device 1 performs a contact operation of moving the mounting table 45 of the stage 40 to bring the wafer W into contact with multiple probes 33 of the probe card 32. The test device 1 according to the present embodiment performs 3D contact correction that corrects the movement amounts of the mounting table 45 in the X-axis direction, the Y-axis direction, and the Z-axis direction in accordance with the load applied to the mounting table 45 from the multiple probes 33 in the contact operation.

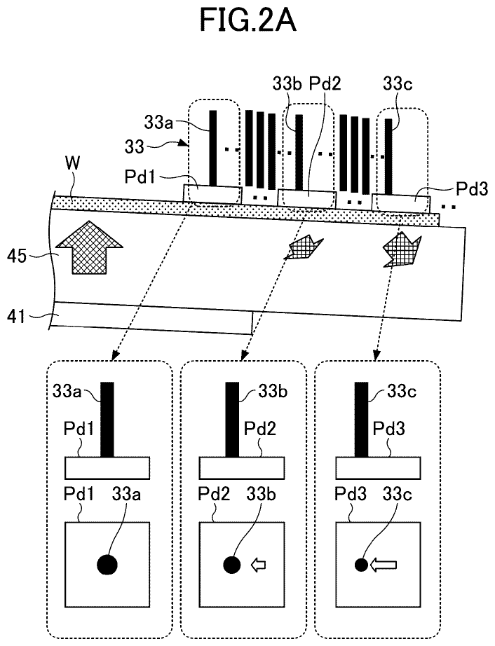

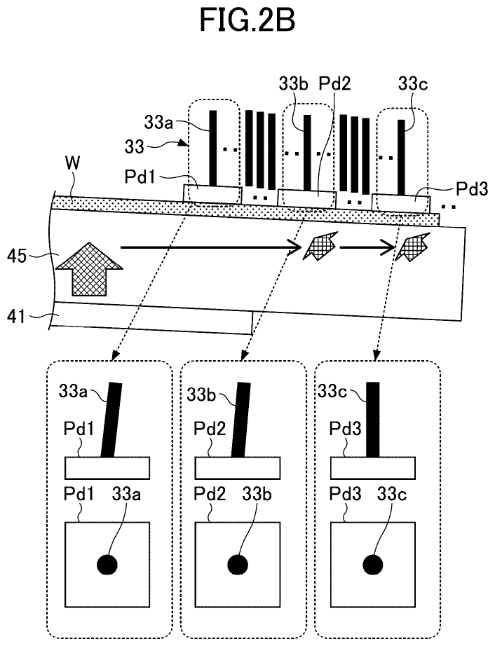

FIG. 2A is a schematic side view illustrating an operation in a case where the 3D contact correction is not performed when the mounting table 45 is moved. FIG. 2B is a schematic side view illustrating an operation in a case where the 3D contact correction is performed when the mounting table 45 is moved. Next, the principle of the 3D contact correction of the test device will be described with reference to FIG. 2A and FIG. 2B.

As illustrated in FIG. 2A, the mounting table 45 (the stage 40) on which the wafer W is mounted in the test device 1 comes into contact with several hundreds to several tens of thousands of probes 33 while the mounting table 45 is raised upward in the Z-axis direction for the testing. Thus, the wafer W receives a high load from the probes 33, and the contact portion of the probes 33 is inclined downward in the Z-axis direction (downward in the vertical direction). In particular, when the probes 33 test the outer peripheral side of the wafer W, a high load is applied to the outer peripheral side of the mounting table 45, and the inclination of the mounting table 45 becomes significant. For example, the outer peripheral side of the mounting table 45 is displaced downward in the Z-axis direction by a high load. Here, the inclination of the mounting table 45 includes a state in which an area around the contact portion (a portion of the mounting table 45) is distorted with respect to other portions, in addition to the inclination of the entire mounting table 45.

The inclination of the mounting table 45 affects the probe mark position and the probe mark size of each of the probes 33 with respect to the wafer W mounted on the mounting surface 48s. Specifically, a probe 33a, which is in contact on the center side of the mounting table 45, comes into contact with the substantially central position of a pad Pd1 of a target semiconductor device, and the size of the probe mark is increased because a strong contact pressure can be applied. with respect to the above, a probe 33b, which is located closer to the outer periphery of the wafer W than the probe 33a is, comes into contact with a position shifted from the substantially central position of a pad Pd2 of the target semiconductor device toward the inner side in the radial direction of the wafer W. Additionally, because the contact pressure of the probe 33b is lower than the contact pressure of the probe 33a, the size of the probe mark thereof is smaller than the size of the probe mark of the probe 33a. Further, a probe 33c, which is located closer to the outer periphery of the wafer W than the probe 33b is, comes into contact with a position further shifted from the substantially central position of a pad Pd3 of the target semiconductor device toward the inner side in the radial direction of the wafer W. Because the contact pressure of the probe 33c is substantially lower than the contact pressure of the probe 33a, the size of the probe mark thereof is substantially smaller than the size of the probe mark of the probe 33a.

The main controller 81 of the controller 80 of the test device 1 performs the 3D contact correction on the inclination of the mounting table 45. In the 3D contact correction when the mounting table 45 is raised, the main controller 81 controls the movement section 41 of the stage 40 to displace the mounting table 45 at the coordinate position (X-axis direction, Y-axis direction, and Z-axis direction) obtained by adding the correction amount in the three-dimensional direction. Here, the 3D contact correction may be performed by the stage controller 49 that actually controls the movement of the stage 40.

For example, as illustrated in FIG. 2B, the controller 80 performs correction to raise the mounting table 45 upward in the Z-axis direction while moving the mounting table 45 in the X-axis direction and the Y-axis direction so as to be located on the outer side in the radial direction of the mounting table 45 in the 3D contact correction. This causes the wafer W mounted on the mounting table 45 to be displaced to approach each of the probes 33 without changing the posture of the mounting table 45. As a result, the probe 33c comes into contact with the substantially central position of the pad Pd3 of the target semiconductor device. Additionally, the size of the probe mark of the probe 33c becomes larger than the size before the correction. Further, the probe 33b also comes into contact with the substantially center position of the pad Pd2 of the target semiconductor device with being slightly curved by the contact pressure from the wafer W. Thus, the size of the probe mark of the probe 33b also becomes larger than the size before the correction. Additionally, the probe 33a is more largely curved by the contact pressure from the wafer W, but is in a contact state in which the substantially central position of the probe Pd1 of the semiconductor device and the size of the probe mark are maintained. Therefore, the contact state of each of the probes 33 can be stabilized by the 3D contact correction.

In the 3D contact correction above, the correction amount in the three-dimensional direction (the X-axis direction, the Y-axis direction, and the Z-axis direction) is important for the probes 33 and the semiconductor device to accurately contact with each other. Here, in conventional 3D contact correction, the correction amount of the 3D contact correction is uniquely set according to, for example, the model of the test device 1, the type of the probe card 32, or the type of the wafer W. However, the correction amount in the three-dimensional direction is set at a value in units of several microns or several nanometers, and a difference is also caused due to an individual difference of the device. Additionally, a difference is also caused by the posture of the probe card 32 in a state where the probe card 32 is attached to the tester 30 or the flatness of the probe card 32 itself. Further, a difference is caused due to the type of the wafer W, which is an object to be tested. Therefore, the correction amount in the three-dimensional direction of the 3D contact correction is required to be set at an appropriate value for each device, each probe card 32, or each wafer W.

In order to absorb the individual differences of the device and the probe card 32 or the type of the wafer W, the test device 1 automatically performs a correction amount calculation process of calculating the correction amount in the three-dimensional direction after the probe card 32 is attached. In the correction amount calculation process, the test device 1 uses the wafer W itself to be actually tested. This enables the test device 1 to obtain the correction amount in the three-dimensional direction in consideration of all the individual difference of the device, the individual difference of the probe card 32 after the attachment, and the difference in the type of the wafer W that the probe card 32 contacts.

In the correction amount calculation process, the test device 1 acquires the position of the mounting table 45 at the conduction start of the probes 33 and the position of the mounting table 45 at the conduction completion of the probes 33, and further calculates the correction amount in the three-dimensional direction based on the respective positions at the conduction start and the conduction completion. In the following, a method of calculating the correction amount will be described in more detail.

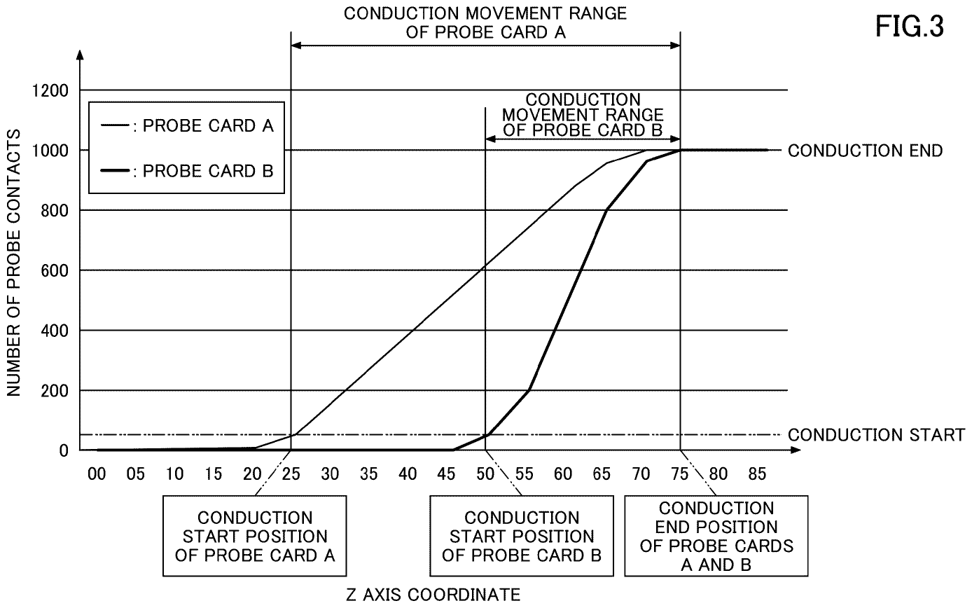

FIG. 3 is a graph indicating changes in a contact state of the wafer W with respect to the probes 33 of the probe card 32 when the mounting table 45 is moved in the Z-axis direction. Here, the horizontal axis in the graph represents the amount of movement of the mounting table 45 in the Z-axis direction, and a numerical value thereof is represented in microns, for example. The vertical axis in the graph represents the number of the conductions of the probes 33 to the wafer W, and the graph indicates an example in which the probe card 32 having 1,000 probes 33 is applied.

Additionally, “conduction start” on the vertical axis of the graph refers to a timing at which the first probe 33 among the multiple probes 33 comes into contact with the wafer W when the mounting table 45 is raised, and “conduction start position” refers to a Z coordinate in the Z-axis direction (a position in the vertical direction) at that time. The “conduction end” on the vertical axis of the graph refers to a timing at which all the multiple probes 33 have completed contact with the wafer W when the mounting table 45 is raised, and the “conduction end position” is a Z coordinate in the Z-axis direction at that time.

The thin solid line in FIG. 3 indicates a contact state of the wafer W to the probes 33 when a probe card A is used, and the thick solid line in FIG. 3 indicates a contact state of the wafer W to the probes 33 when a probe card B is used. That is, when the mounting table 45 is raised, in the probe card A, the first probe 33 is in contact at a position where the Z coordinate of the mounting table 45 in the Z-axis direction is low. Then, the number of contacts of the probes 33 gradually increases as the mounting table 45 is raised after the conduction start, and the number of contacts becomes constant at the conduction end position where all the probes 33 are in contact. With respect to the above, in the probe card B, the first probe 33 is in contact at a position where the Z coordinate of the mounting table 45 in the Z-axis direction is higher than the Z coordinate of the probe card A in the Z-axis direction. Then, the number of contacts of the probes 33 increases rapidly as the mounting table 45 is raised after the conduction start, and the number of contacts becomes constant at the conduction end position where all the probes are in contact. The conduction end positions of the probe card A and the probe card B are the same positions. Here, if the form of the probe card 32 (the number of the probes 33) or the attachment state of the probe card 32 is different, the conduction end position of the probe card A and the conduction end position of the probe card B are different from each other.

That is, in FIG. 3, the movement range in the Z-axis direction from the time when the first probe 33 of the probe card A comes into contact with the wafer W to the time when all the probes 33 come into contact with the wafer W (hereinafter, referred to as a conduction movement range) is longer than a conduction movement range of the probe card B. The reason why the conduction movement range is long is that the mounting table 45 is inclined, the posture or flatness of the probe card A is poor, the flatness of the wafer W is poor, or the like. When the probe card A and the probe card B are attached to the same test device 1 and the same wafer W is tested, the posture or flatness of the probe card A can be regarded as being worse than the posture or flatness of the probe card B. However, it is found that, even if the long conduction movement range is caused by any factor, the correction amount in the three-dimensional direction that absorbs the individual differences of the device and the probe card 32 and the type of the wafer W can be calculated by extracting the conduction movement range after the probe card 32 is attached.

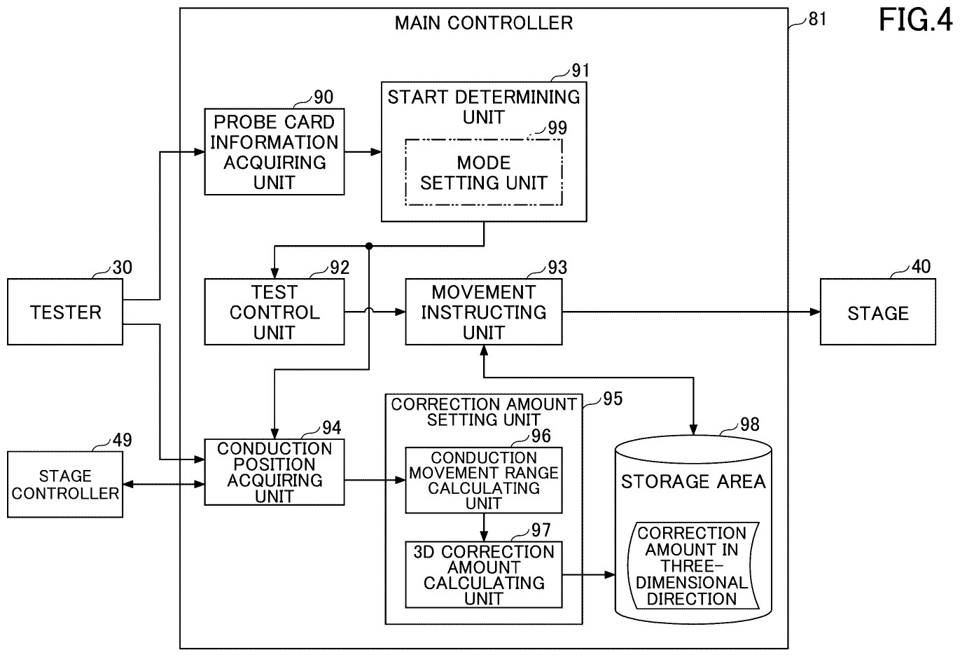

Thus, the main controller 81 performs the correction amount calculation process (a correction amount calculation method) of calculating the correction amount in the three-dimensional direction after the probe card 32 is attached and before the electrical test of the wafer W is performed. Then, the main controller 81 performs the 3D contact correction in the contact operation during the electrical test of the wafer W by using the correction amount in the three-dimensional direction obtained by the correction amount calculation process. The main controller 81 constructs functional blocks for performing the correction amount calculation process and the 3D contact correction as illustrated in FIG. 4 by the processor 82 executing a program recorded in the memory 83.

FIG. 4 is a block diagram illustrating the functional blocks for performing the correction amount calculation process and the 3D contact correction. Specifically, the main controller 81 includes a probe card information acquiring unit 90, a start determining unit 91, a test control unit 92, a movement instructing unit 93, a conduction position acquiring unit 94, a correction amount setting unit 95, a storage area 98, and the like.

When the probe card 32 is attached in the test device 1, the probe card information acquiring unit 90 acquires attachment information on the probe card 32 from the tester 30, stores the attachment information in the memory 83, and outputs the attachment information to the start determining unit 91. The attachment information includes, for example, identification information of the probe card 32, the number of the probes 33, the power for conducting the probes 33 at the conduction start, the power for conducting the probes 33 at the conduction completion, the attachment time, and the like.

When acquiring the attachment information from the probe card information acquiring unit 90, the start determining unit 91 determines whether to perform or not to perform the correction amount calculation process. As an example, when recognizing that the probe card 32 is replaced and the wafer W is set on the loader 20 (or the mounting table 45), the start determining unit 91 determines the start of the correction amount calculation process. Here, it may be configured such that the correction amount calculation process is started based on the operation of the user interface 85 by the user. When determining the start of the correction amount calculation process, the start determining unit 91 outputs a start instruction to the test control unit 92, the conduction position acquiring unit 94, and the like.

The test control unit 92 controls the operation in the electrical test of the wafer W. Additionally, in the correction amount calculation process, the test control unit 92 performs control to measure the conduction timing by operating the stage 40 to bring the probes 33 of the probe card 32 into contact with the wafer W mounted on the mounting table 45, as in the electrical test of the wafer W. Here, in the correction amount calculation process, the contact operation of the mounting table 45 is performed without performing the 3D contact correction, and the wafer W is brought into contact with the probes 33.

The movement instructing unit 93 outputs a movement instruction to the stage 40 (the stage controller 49) in response to receiving a control instruction output by the test control unit 92. For example, in the correction amount calculation process, the mounting table 45 is moved in the horizontal direction (the X-axis direction and the Y-axis direction) and is raised and lowered in the vertical direction (the Z-axis direction) so that the probes 33 of the probe card 32 come into contact with the center of the wafer W on the mounting table 45. In the electrical test of the wafer w, the movement instructing unit 93 moves the stage 40 by using the correction amount in the three-dimensional direction stored in the storage area 98.

The conduction position acquiring unit 94 acquires information on the conduction position where the wafer W is in contact with the probe 33 from the tester 30 based on the start instruction of the correction amount calculation process from the start determining unit 91. As described above, the information on the conduction position includes the conduction start position where the first probe 33 among the probes 33 is in contact with the wafer W and the conduction end position where all the probes 33 are in contact with the wafer W (see also FIG. 3). The tester 30 detects the conduction timing by supplying power to the probes 33 in the correction amount calculation process, and when receiving the conduction timing, outputs the conduction timing to the main controller 81. When receiving the information on the conduction timing of the tester 30, the conduction position acquiring unit 94 requests the Z coordinate in the Z-axis direction from the stage controller 49. The stage controller 49 holds a three-dimensional coordinate position by feedforward control (or acquires the three-dimensional coordinate position by feedback control from the movement section 41) when the mounting table 45 moves, and transmits the information to the conduction position acquiring unit 94 based on the request.

The correction amount setting unit 95 calculates the correction amount in the three-dimensional direction based on the information on the conduction position received from the conduction position acquiring unit 94. Thus, the correction amount setting unit 95 includes a conduction movement range calculating unit 96 and a 3D correction amount calculating unit 97.

The conduction movement range calculating unit 96 calculates the conduction movement range based on the conduction start position and the conduction end position included in the information on the conduction position. For example, the conduction movement range can be easily obtained by subtracting the conduction start position from the conduction end position.

The 3D correction amount calculating unit 97 calculates the correction amount in the three-dimensional direction based on a position of the contact portion that the probe 33 contacts and the conduction movement range calculated by the conduction movement range calculating unit 96. For example, the correction amount in the three-dimensional direction is individually calculated as a movement correction amount in the X-axis direction, a movement correction amount in the Y-axis direction, and a movement correction amount in the Z-axis direction, and each of the movement correction amounts is calculated as a larger value as the conduction movement range increases. Then, the correction amount setting unit 95 stores the calculated correction amount in the three-dimensional direction in the storage area 98. This completes the correction amount calculation process after the replacement of the probe card 32.

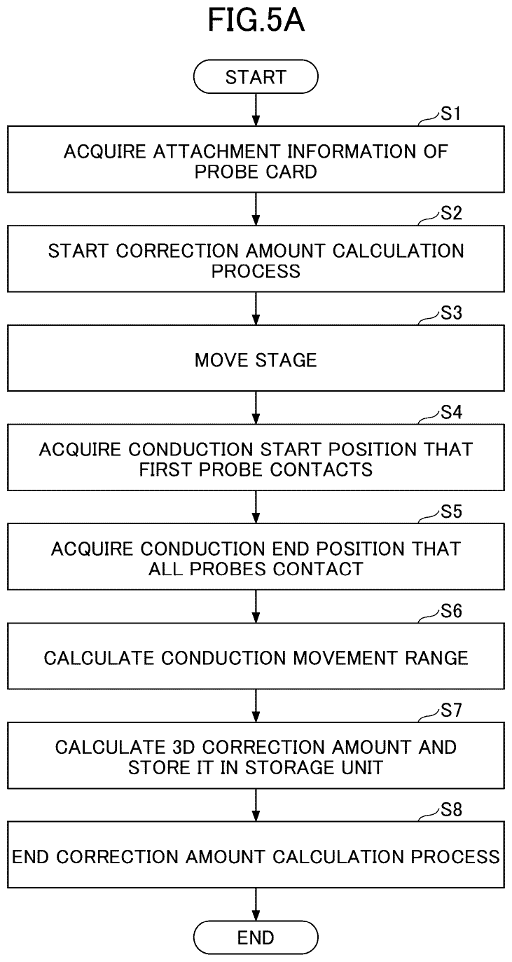

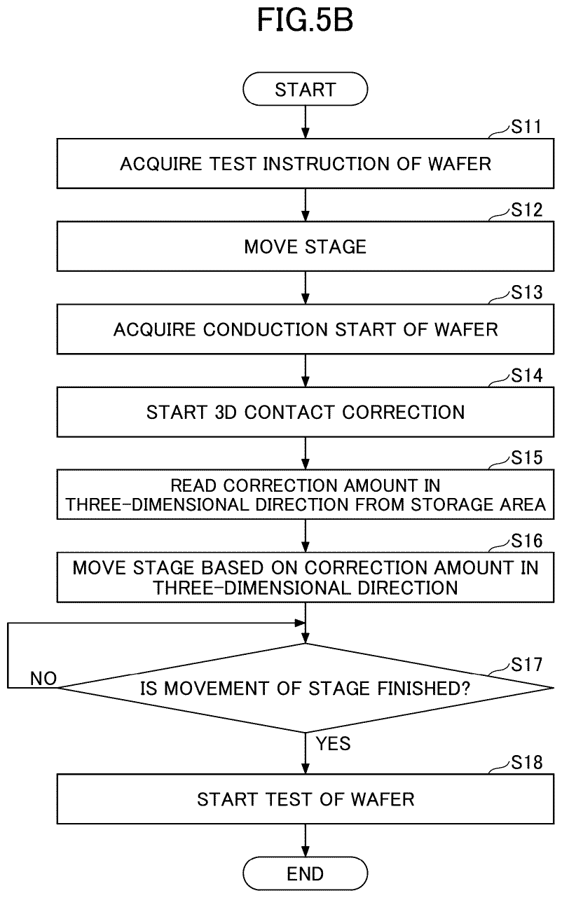

The test device 1 according to the first embodiment is basically configured as described above, and a test method of the test device 1 will be described below with reference to FIG. 5A and FIG. 5B. FIG. 5A is a flowchart illustrating a processing flow of the correction amount calculation process (the correction amount calculation method) of the test method. FIG. 5B is a flowchart illustrating a processing flow of a test process (a contact operation of the electrical test of the wafer W) of the test method.

The test device 1 performs an attachment operation of attaching the probe card 32 to the tester 30 for testing the wafer W. As illustrated in FIG. 5A, when the probe card 32 is attached, the probe card information acquiring unit 90 of the main controller 81 acquires the attachment information on the probe card 32 (step S1).

The start determining unit 91 monitors the attachment of the probe card 32 and the setting of the wafer W on the loader 20, and determines the start of the correction amount calculation process in order to obtain the correction amount in the three-dimensional direction corresponding to the attached probe card 32 (step S2).

When the correction amount calculation process is started, the test control unit 92 moves the stage 40 to transfer the wafer W mounted on the mounting table 45 (step S3). At this time, the stage 40 moves the mounting table 45 in the horizontal direction so that the center position of the wafer W faces the center position of the probes 33 of the probe card 32. Subsequently, the stage 40 raises the mounting table 45 along the vertical direction (the Z-axis direction) to bring the wafer W into contact with the probes 33.

When the mounting table 45 is raised, the conduction position acquiring unit 94 acquires the conduction start position where the first probe 33 among the probes 33 comes into contact with the wafer W from the tester 30 and the stage controller 49 (step S4). Even after the conduction start, the test control unit 92 continues to raise the mounting table 45. Then, the conduction position acquiring unit 94 acquires the conduction end position where all the probes 33 are in contact with the wafer W from the tester 30 and the stage controller 49 (step S5).

When the conduction position acquiring unit 94 finishes acquiring the conduction position, the conduction movement range calculating unit 96 of the correction amount setting unit 95 calculates the conduction movement range based on the acquired conduction start position and conduction end position (step S6).

Subsequently, the 3D correction amount calculating unit 97 of the correction amount setting unit 95 calculates the correction amount in the three-dimensional direction based on the calculated conduction movement range, and appropriately stores the correction amount in the three-dimensional direction in the storage area 98 of the memory 83 (step S7). As described above, the correction amount in the three-dimensional direction is calculated as the movement correction amount in each of the X-axis direction, the Y-axis direction, and the Z-axis direction.

Finally, the main controller 81 performs an end process of ending the correction amount calculation process (step S8). For example, in the end process, the operation of the tester 30 is stopped and the stage 40 is moved to return the wafer W on the mounting table 45 to the loader 20 under the control of the test control unit 92.

As described above, the test device 1 can obtain an appropriate correction amount in the three-dimensional direction by performing the correction amount calculation process before the testing of the wafer W. The correction amount in the three-dimensional direction depends on the individual difference of the device, the individual difference (including the posture, flatness, and the like) of the probe card 32 attached to the tester 30, or the type of the wafer W. Therefore, the test device 1 can perform the 3D contact correction with high accuracy during the actual electrical testing (test process) of the wafer W.

Specifically, as illustrated in FIG. 5B, the main controller 81 receives a test operation of performing the electrical test of the wafer W from the user via the user interface 85 (step S11), and starts the testing of the wafer W.

In the electrical testing of the wafer w, the test control unit 92 delivers the wafer W from the loader 20 to the mounting table 45, and then moves the stage 40 to transfer the wafer W mounted on the mounting table 45 (step S12). At this time, the stage 40 moves the mounting table 45 in the horizontal direction to cause the contact position of the wafer W to face the probes 33, and then raises the mounting table 45 along the vertical direction (the Z-axis direction).

When the mounting table 45 is raised, the first probe 33 among the probes 33 comes into contact with the wafer W, and thus the conduction between the tester 30 and the wafer W is started (step S13). The test control unit 92 performs the 3D contact correction for the contact operation of the mounting table 45, in response to the start of conduction (step S14).

In the 3D contact correction, the movement instructing unit 93 reads the correction amount in the three-dimensional direction stored in the storage area 98 by the correction amount calculation process (step S15). Then, the movement instructing unit 93 calculates a target movement amount of the mounting table 45 in the three-dimensional direction by adding the correction amount in the three-dimensional direction to the movement amount received from the test control unit 92, and moves the stage 40 in accordance with the target movement amount (step S16).

Additionally, at the time of the 3D contact correction, the test control unit 92 determines whether the movement of the stage 40 is finished (step S17). If the stage 40 is moving (step S17: NO), the 3D contact correction is continued. If the movement of the stage 40 is finished (step S17: YES), the process proceeds to step S18.

In step S18, the test control unit 92 starts the testing of the wafer W by the tester 30. The test device 1 performs the 3D contact correction described above, thereby bringing the probes 33 into contact with the target device on the wafer W with high accuracy. Therefore, the test device 1 can stably perform the electrical test of the wafer W by the tester 30.

Here, naturally, the test device 1, the correction amount calculation method, and the test method of the present disclosure are not limited to the above-described embodiments, and various modifications can be made. For example, the timing of performing the correction amount calculation method is not limited as long as it is before the electrical test of the wafer W is performed, and may not be immediately after the replacement of the probe card 32.

### Second Embodiment

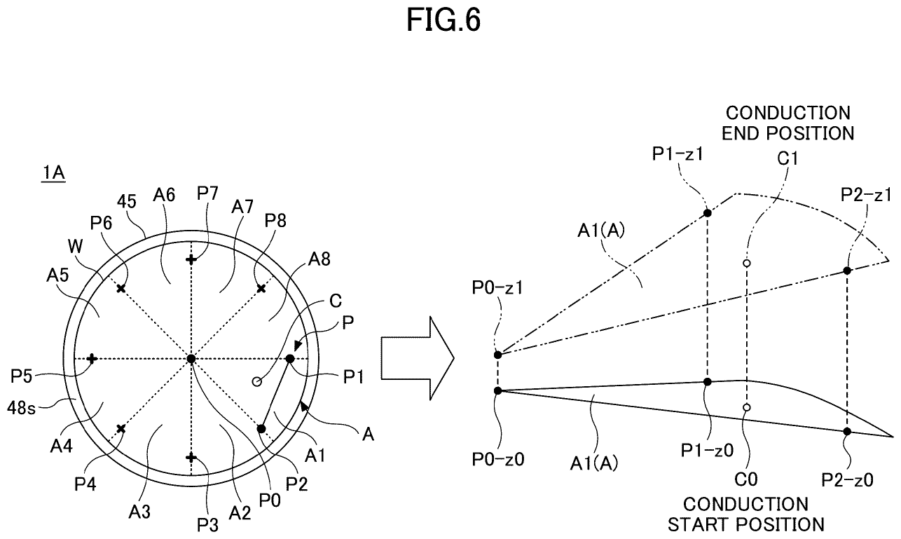

FIG. 6 is a schematic plan view illustrating a mounting table 45 of a test device 1A according to a second embodiment and an explanatory diagram illustrating a correction amount of an area A in the three-dimensional direction. As illustrated in FIG. 6, the test device 1A according to the second embodiment is different from the test device 1 according to the first embodiment in that the correction amount in the three-dimensional direction is obtained for each of the multiple areas A.

The multiple areas A form divided surfaces on the mounting surface 48s of the mounting table 45. To form the surface, each of the area A is formed to have three vertices P. In the example of FIG. 6, each of the areas A is set as a triangle, the areas A being obtained by dividing the surface at 45° increments with the center of the mounting surface 48s being a base point into eight triangles, and is formed to have a common vertex P0 at the center and to have respective vertices P1 to P8 on the outer peripheral side. Here, the shape of each of the areas A is not limited to a triangle, and may be a polygon having four or more vertices P.

The vertices P of each of the areas A can be suitably set, and can be set according to the probe card 32 attached to the tester 30 or the wafer W to be tested. The controller 80 may automatically set the multiple vertices P based on the information on the probe card 32, and can naturally set each of the areas A by setting the multiple vertices P. For example, as illustrated in FIG. 6, in a configuration in which the vertex PO is set at the center of the mounting surface 48s and the other vertices P1, P2, . . . are set on the outer peripheral side of the mounting surface 48s, the other vertices P1, P2, . . . is preferably set on the outer side of the center of the radius of the mounting surface 48s.

In the correction amount calculation process, the main controller 81 detects the conduction movement range in the Z-axis direction in each of the areas A by bringing the probes 33 of the probe card 32 into contact with each of the eight areas A. The portion of each of the areas A that the probes 33 contact is not particularly limited, and is only required to be inside each of the areas A. In FIG. 6, a point at which the center of the probes 33 comes into contact with the area A1 is indicated by C, for example, and the contact point C is set at the center of gravity in a plane surrounded by the vertices P0, P1, and P2 forming the area A1.

The conduction position acquiring unit 94 of the main controller 81 acquires a conduction start position C0 and a conduction end position C1 of the contact point C in the correction amount calculation process. The correction amount setting unit 95 calculates the coordinate of each vertex P in the Z-axis direction based on the acquired conduction start position C0, and calculates the coordinate of each vertex P in the Z-axis direction based on the acquired conduction end position C1. As an example, as illustrated in the right drawing of FIG. 6, the correction amount setting unit 95 calculates a conduction start position P0-z0 of the vertex P0, a conduction start position P1-z0 of the vertex P1, and a conduction start position P2-z0 of the vertex P2, based on the conduction start position C0 of the area A1. Further, the correction amount setting unit 95 calculates a conduction end position P0-z1 of the vertex P0, a conduction end position P1-z1 of the vertex P1, and a conduction end position P2-z1 of the vertex P2, based on the conduction end position C1 of the area A1.

After calculating the respective conduction positions, the correction amount setting unit 95 calculates the conduction movement range of each of the three vertices P constituting each of the areas A. Using the right drawing of FIG. 6 as an example, in the area A1, a conduction movement range of the vertex P0, a conduction movement range of the vertex P1, and a conduction movement range of the vertex P2 are calculated. The correction amount setting unit 95 can calculate the correction amount in the three-dimensional direction as the entire surface of the area A1 by these conduction movement ranges, and stores the calculated correction amount in the three-dimensional direction of the area A1 in the storage area 98.

The main controller 81 calculates all the correction amounts in the three-dimensional direction for the areas A in the correction amount calculation process, and stores the correction amounts in the storage area 98. This allows the test device 1 to read the correction amount in the three-dimensional direction for each of the areas A from the storage area 98 when the probes 33 come into contact with the wafer W in the electrical test (test process) of the wafer W. For example, when the center (the contact point C) of each of the probes 33 contacts the area A1 of the wafer W, the correction amount in the three-dimensional direction as the entire surface of the area A1 is read to perform the 3D contact correction. This enables the main controller 81 to perform the 3D contact correction with an appropriate correction amount in accordance with the inclination of the probe card 32 and the mounting table 45 in each of the areas A.

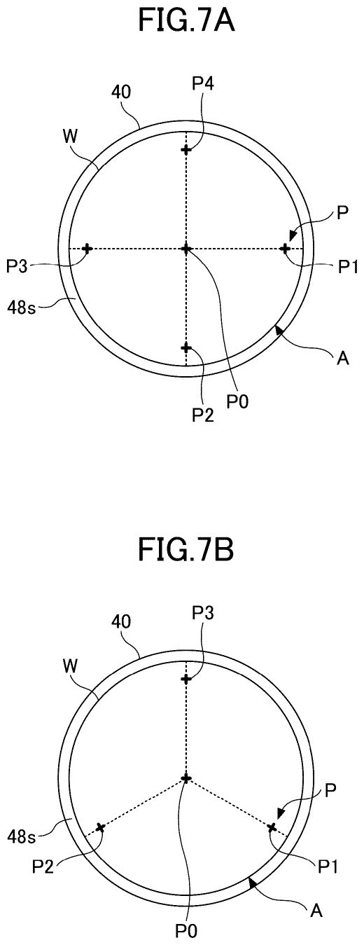

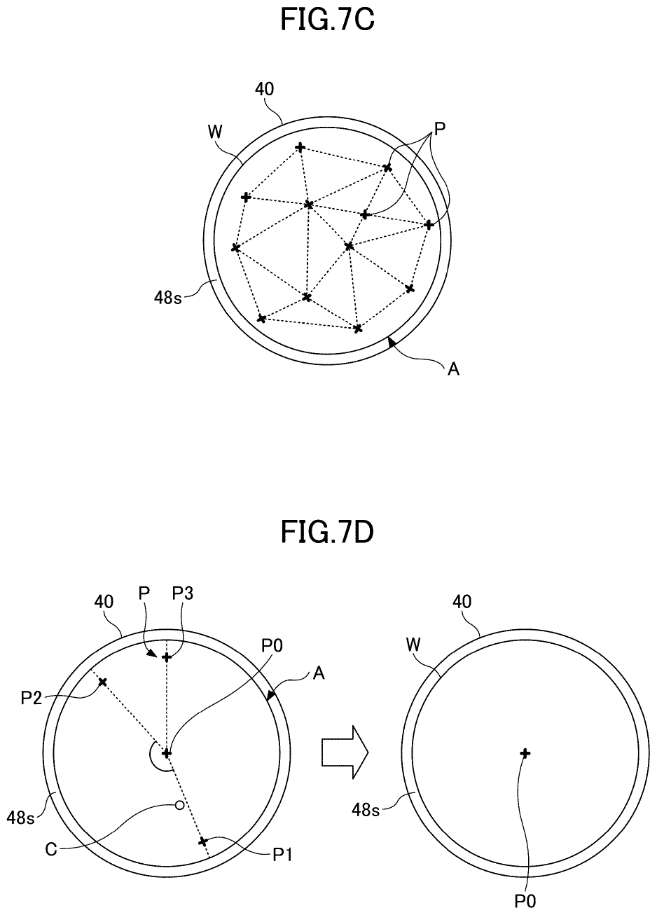

Here, the setting of the areas A into which the mounting surface 48s is divided is not limited to the pattern illustrated in FIG. 6, and various patterns can be adopted. In the following, some division patterns of the areas A will be exemplified with reference to FIG. 7A to FIG. 7D. FIG. 7A is an explanatory diagram illustrating a division pattern of multiple areas A in a correction amount calculation process according to a first modified example. FIG. 7B is an explanatory diagram illustrating a division pattern of multiple areas A in a correction amount calculation process according to a second modified example. FIG. 7C is an explanatory diagram illustrating a division pattern of multiple areas A in a correction amount calculation process according to a third modified example. FIG. 7D is an explanatory diagram illustrating a division pattern of multiple areas A in a correction amount calculation process according to a fourth modified example.

As in the first modified example illustrated in FIG. 7A, the test device 1A may divide the surface into four areas A at every 90° with the center of the mounting surface 48s being a base point in the correction amount calculation process. By dividing the areas A in such a way, the test device 1A can improve the efficiency of the processing even if the correction amount calculation process is performed on all the multiple areas A, and can satisfactorily perform the 3D contact correction based on the correction amount in the three-dimensional direction for each of the multiple areas A.

Additionally, as in the second modified example illustrated in FIG. 7B, the test device 1A may divide the surface into three areas A at every 120° with the center of the mounting surface 48 s being a base point in the correction amount calculation process. This allows the test device 1 to perform the processing more efficiently.

Further, as in the third modified example illustrated in FIG. 7C, the test device 1A may be configured to set multiple random vertices P on the mounting surface 48s in the correction amount calculation process and form multiple triangular areas A, each of which is formed by connecting the vertices P close to each other. Even when multiple random areas A are formed in such a way, the correction amount in the three-dimensional direction for each of the areas A can be calculated by detecting the conduction movement range for each of the areas A.

In short, the areas A into which the mounting surface 48s is divided are only required to form portions of the mounting surface 48s, and can be set in various patterns. If the number of the areas A dividing the mounting surface 48s is greater, the correction amount in the three-dimensional direction is held for each area A, and thus the accuracy of the 3D contact correction can be further increased. Conversely, if the number of the areas A into which the mounting surface 48s is divided is less, the efficiency of the correction amount calculation process can be improved. The main controller 81 can be configured to automatically set the division pattern of the area A (the multiple vertices P) based on the information on the probe card 32. For example, the main controller 81 may increase the number of divisions of the areas A when the number of the probes 33 or the contact range is small, and may decrease the number of divisions of the areas A when the number of the probes 33 or the contact range is large.

However, as in the fourth modified example illustrated in FIG. 7D, when a triangle in which the angle of one vertex P is 150° or greater is formed in the triangles formed by the vertices P in the correction amount calculation process, the test device 1A performs the correction amount calculation process in a single point mode (the first embodiment) without performing the correction amount calculation process in the multipoint mode. That is, when the angle of one vertex P is 150° or greater, as illustrated in FIG. 7D, even if the contact point C is within the area A1, the correction amount in the three-dimensional direction of the area A1 may not be accurately reflected. For example, in FIG. 7D, the contact point C is near the vertex P1, but the correction amount in the three-dimensional direction calculated based on the contact point C does not reflect the correction amount in the three-dimensional direction near the vertex P2.

Therefore, when the vertices P are automatically set according to the probe card 32, the main controller 81 preferably selects the single point mode or the multipoint mode as appropriate based on the positions of the vertices P. As an example, as indicated by the dash-dot-dot line in FIG. 4, the main controller 81 includes a mode setting unit 99 in the start determining unit 91, and sets multiple vertices P dividing the mounting surface 48s and multiple areas A based on the vertices P in the mode setting unit 99. Then, the mode setting unit 99 preferably selects the correction amount calculation process in the single point mode when there is a vertex P having an angle of 150° or greater among the vertices P.

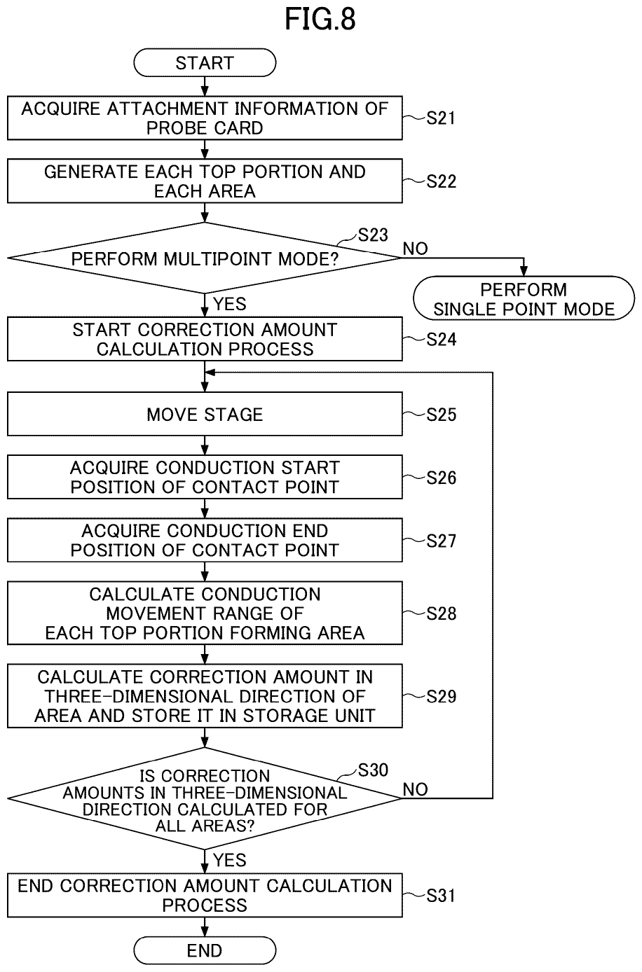

The test device 1A according to the second embodiment is basically configured as described above, and a processing flow of the test method (the correction amount calculation method) according to the second embodiment will be described below with reference to FIG. 8. FIG. 8 is a flowchart illustrating the correction amount calculation method according to the second embodiment.

When the probe card 32 is attached, the probe card information acquiring unit 90 of the main controller 81 according to the second embodiment acquires the attachment information on the probe card 32 (step S21).

The mode setting unit 99 of the start determining unit 91 generates the vertices P and the areas A dividing the mounting surface 48s based on the attachment information on the probe card 32 (step S22). Then, the mode setting unit 99 determines whether to perform the multipoint mode or the single point mode based on the generated vertices P and the areas A (step S23). At this time, the mode setting unit 99 determines not to perform the multipoint mode when there is an area A having a vertex P of 150° or greater as described above (step S23: NO), and performs the single point mode illustrated in FIG. 5A. When there is no area having a vertex P of 150° or greater, the mode setting unit 99 determines to perform the multipoint mode (step S23: YES), and proceeds to step S24.

In step S24, the start determining unit 91 monitors the setting of the wafer W to the loader 20, and determines the start of the correction amount calculation process in order to obtain the correction amount in the three-dimensional direction corresponding to the attached probe card 32.

When the correction amount calculation process is started, the test control unit 92 moves the stage 40 to transfer the wafer W mounted on the mounting table 45 (step S25). At this time, the stage 40 moves the mounting table 45 in the horizontal direction so that the predetermined area A appropriately faces the center position (the contact point C) of the probes 33 of the probe card 32. Subsequently, the stage 40 raises the mounting table 45 along the vertical direction (the Z-axis direction) to bring the wafer W in the predetermined area A into contact with the probes 33.

When the mounting table 45 is raised, the conduction position acquiring unit 94 acquires the conduction start position where the first probe 33 among the probes 33 comes into contact with the wafer W from the tester 30 and the stage controller 49 (step S26). After the start of conduction, the test control unit 92 continues to raise the mounting table 45. Then, the conduction position acquiring unit 94 acquires the conduction end position where all the probes 33 come into contact with the wafer W from the tester 30 and the stage controller 49 (step S27).

After the acquisition, the conduction movement range calculating unit 96 calculates the conduction start position and the conduction end position of each of the vertices P of the predetermined area A, and further calculates the conduction movement range of each of the vertices P based on the conduction start position and the conduction end position of the vertex P (step S28). Subsequently, the 3D correction amount calculating unit 97 calculates the correction amount of the predetermined area A in the three-dimensional direction based on the calculated conduction movement range of each of the vertices P, and stores the correction amount in the three-dimensional direction in the appropriate storage area 98 of the memory 83 (step S29).

Subsequently, the main controller 81 determines whether the calculation of the correction amount in the three-dimensional direction in the predetermined area A has been performed for all the areas A (step S30). If there is an area A for which the calculation of the correction amount in the three-dimensional direction has not been performed (step S30: NO), the area A for which the calculation is to be performed is changed, and the process returns to step S25. Then, the correction amount in the three-dimensional direction of each of the areas A is calculated by repeating steps S25 to S29 in the same manner.

When the correction amounts in the three-dimensional direction of all the areas have been calculated (step S30: YES), the process proceeds to step S31. In step S31, the main controller 81 performs an end process of ending the correction amount calculation process, and ends the correction amount calculation process in the multipoint mode.

In the subsequent test process of electrically testing the wafer W, the test control unit 92 and the movement instructing unit 93 read, based on the contact point C of the probes 33, the correction amount in the three-dimensional direction for each of the multiple corresponding areas A from the storage area 98 when the stage 40 is moved in the Z-axis direction. Then, the test device 1 performs the 3D contact correction based on the correction amount in the three-dimensional direction of the corresponding area A. This can correct the movement of the stage 40 with high accuracy for each of the areas A, and bring the target semiconductor device of the wafer W into contact with the probes 33 more accurately.

### Third Embodiment

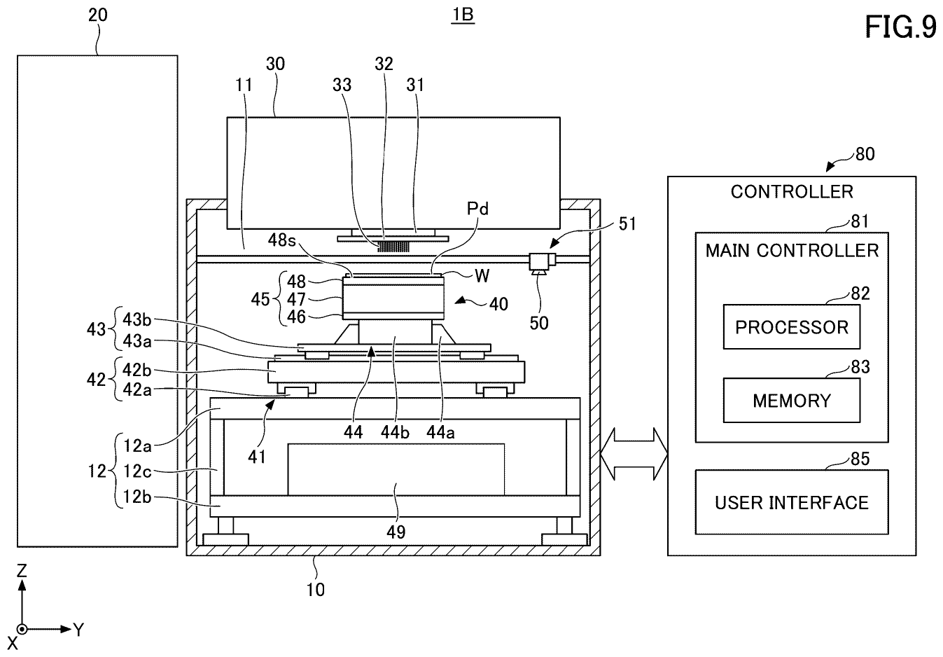

FIG. 9 is a schematic cross-sectional view illustrating a test device 1B according to a third embodiment. As illustrated in FIG. 9, the test device 1B according to the third embodiment is different from the test devices 1 and 1A described above in that the test device 1B uses a probe mark formed on each of the pads Pd by the overdrive as the information on the contact state between each of the probes 33 and the wafer W in the correction amount calculation process. That is, the controller 80 of the test device 1B calculates the correction amount in the three-dimensional direction based on the probe mark formed on each of the pads Pd and the Z coordinate of the stage 40.

Specifically, the test device 1B includes a camera 50 configured to image the wafer W and a camera movement section 51 configured to move the camera 50 in the test space 11 where the stage 40 is disposed. For example, the camera 50 is installed on the upper side of the test space 11 such that an optical lens faces downward in the vertical direction. The camera 50 is held by the camera movement section 51 to be movable relative to the stage 40 and can be moved to an imaging position above the wafer W mounted on the mounting table 45 in the vertical direction. The camera movement section 51 includes a drive source, a drive transmitter, multiple of rollers, and a rail (not illustrated), and moves the camera 50 to an appropriate horizontal coordinate position based on an instruction from the controller 80. Here, the relative movement between the wafer W and the camera 50 is not limited to the operation of the camera movement section 51, and the wafer W may be positioned at the imaging position of the camera 50 by the operation of the stage 40.

In the correction amount calculation process, the controller 80 raises the wafer W to bring the probes 33 into contact with the pads Pd, and then captures, by the camera 50, an image of chips on the wafer W that are in contact. A probe mark formed when the probe 33 comes into contact with the pad Pd of the semiconductor device of the wafer W is imaged as image information. The probe mark of each of the pads Pd is formed in a different state (the probe mark size, the probe mark position, and the like) for each of the multiple probes 33 due to the overdrive of the wafer W in the Z-axis direction. For example, a probe mark formed when a predetermined probe 33 comes into contact with an opposed pad Pd for the first time and a probe mark formed when the same probe 33 comes into contact with the same opposed pad Pd for the second time are in different states. Thus, the controller 80 can easily extract the probe mark of each of the pads Pd imaged this time by performing appropriate image processing (for example, processing of obtaining a difference from the image of the pad Pd last time or in a state where there is no probe mark) on the acquired image information.

Therefore, in the correction amount calculation process, the controller 80 performs a probe mark formation operation of forming the probe mark by moving the wafer W in the Z-axis direction and bringing the probes 33 into contact with the pads Pd multiple times while changing the Z coordinate, and performs imaging by the camera 50 for each probe mark formation operation. With this, the image information for each of the multiple Z coordinates is obtained, and the controller 80 can count the number of the probe marks of the pads Pd in each image information. The number of the probe marks extracted from the image information of each Z coordinate represents the number of contacts of the probes 33 with the pads Pd. Therefore, the controller 80 can acquire information on the contact state in which each Z coordinate is associated with the number of the probe marks, and can grasp the posture and flatness of the probe card 32 in more detail.

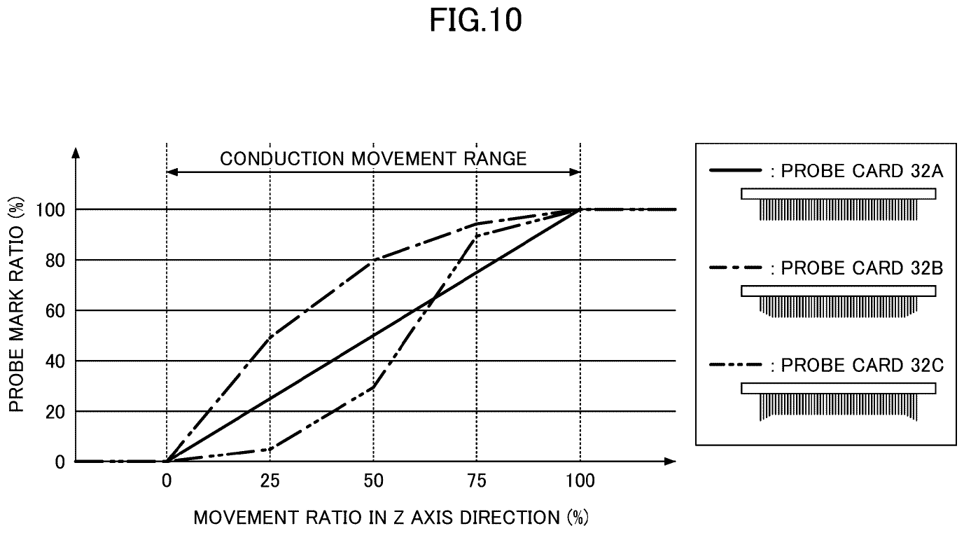

FIG. 10 is a graph indicating an example of changes in the Z coordinate and the number of the probe marks. For example, the controller 80 sets the movement rate in the conduction movement range in the Z-axis direction by setting the conduction start position to 0% in the Z coordinate and the conduction end position to 100% in the Z coordinate. Then, the controller 80 sets multiple positions into which the movement rate of the conductive movement range is equally divided (for example, 25%, 50%, and 75%) as the Z coordinate where the imaging is performed by the camera 50. That is, the controller 80 extracts the number of the probe marks at 25% movement from the conduction start position in the conduction movement range, the number of the probe marks at 50% movement from the conduction start position in the conduction movement range, and the number of the probe marks at 75% movement from the conduction start position in the conduction movement range. Here, the number and positions of the Z coordinate for extracting the number of the probe marks can be suitably set.

The changes in the number of the probe marks on the Z-axis direction has different aspects depending on the form of the probes 33. As an example, a probe card 32A includes the probes 33 having flat lower ends, and thus indicates changes in which the number of the probe marks linearly increases as the Z coordinate increases. Specifically, the ratio of the number of the probe marks to the total number of the probes (hereinafter referred to as a probe mark ratio) is 25% at 25% in the Z coordinate, the probe mark ratio is 50% at 50% in the Z coordinate, and the probe mark ratio is 75% at 75% in the Z coordinate.

A probe card 32B includes the probes 33 that are short on the outer peripheral side and long on the inner side, and thus indicates changes in which the number of the probe marks first increases rapidly and then the number of the probe marks increases gradually. Specifically, the probe mark ratio is 50% at 25% in the Z coordinate, the probe mark ratio is 80% at 50% in the Z coordinate, and the probe mark ratio is 95% at 75% in the Z coordinate. Additionally, a probe card 32C includes the probes 33 that are long on the outer peripheral side and short on the inner side, and thus indicates changes in which the number of the probe marks first increases gradually and then the number of the probe marks increases rapidly. Specifically, the probe mark ratio is 5% at 25% in the Z coordinate, the probe mark ratio is 30% at 50% in the Z coordinate, and the probe mark ratio is 90% at 75% in the Z coordinate.

The controller 80 can more appropriately calculate the correction amount in the three-dimensional direction by recognizing the changes in the number of the probe marks (the probe mark ratio) as illustrated in FIG. 10 in the correction amount calculation process. For example, the controller 80 increases the correction amount of the stage 40 in the three-dimensional direction in the initial stage of the movement in the Z-axis direction, in which the number of the probe marks rapidly increases (for example, in a range of 0% to 50% in the Z coordinate is), as in the probe card 32B. Additionally, the controller 80 reduces the correction amount of the stage 40 in the three-dimensional direction in the later stage of the movement in the Z-axis direction (for example, in a range of 50% to 100% in the Z coordinate). This enables the test device 1B to bring each of the probes 33 of the probe card 32B into contact with the pad Pd with higher accuracy. Conversely, the controller 80 reduces the correction amount of the stage 40 in the three-dimensional direction in the initial stage of the movement in the Z-axis direction, in which the number of the probe marks gradually increases (for example, in a range of 0% to 50% in the Z coordinate), as in the probe card 32C. Additionally, the controller 80 increases the correction amount of the stage 40 in the three-dimensional direction in the later stage of the movement in the Z-axis direction (for example, in a range of 50% to 100% in the Z coordinate). This enables the test device 1B to bring each of the probes 33 of the probe card 32C into contact with the pad Pd with higher accuracy.

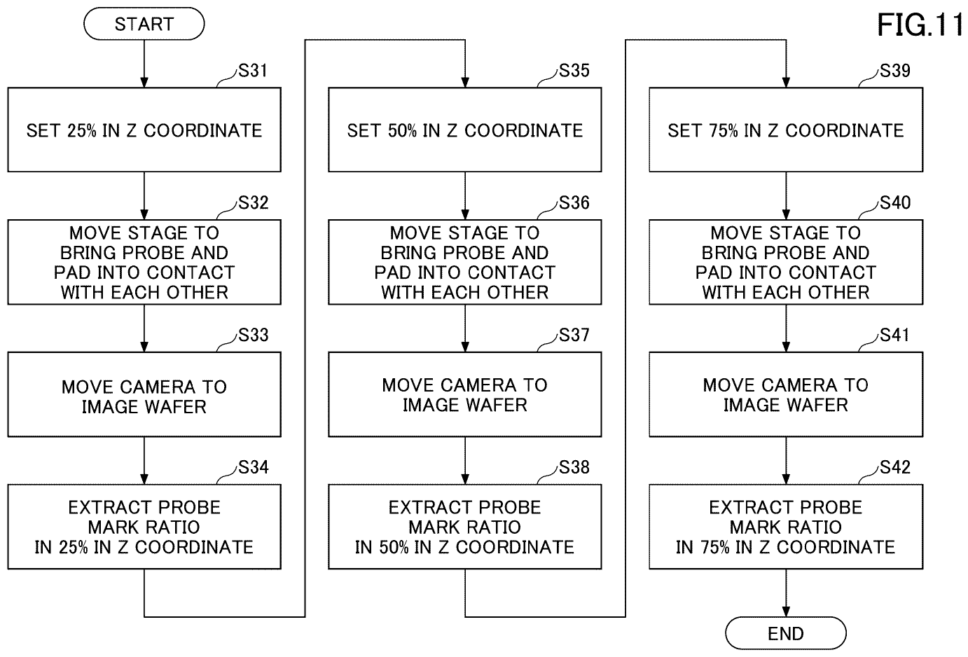

The test device 1B according to the third embodiment is basically configured as described above, and a processing flow of a correction amount calculation process of the test device 1B will be described below with reference to FIG. 11. FIG. 11 is a flowchart of the correction amount calculation process according to the third embodiment.

In the correction amount calculation process, the controller 80 first sets to acquire the probe mark ratio at 25% in the Z coordinate (step S31). Based on this setting, the controller 80 moves the stage 40 on which the wafer W is mounted, and brings the probes 33 into contact with the pads Pd and the overdrive operation is performed (step S32). When the stage 40 reaches the position of 25% in the Z coordinate, the controller 80 lowers the stage 40 to separate the pads Pd from the probes 33.

Subsequently, the controller 80 moves the camera 50 to the imaging position of the wafer W and images the wafer W (step S33). When the controller 80 acquires the image information of the camera 50, the controller 80 extracts the number of the probe marks (the probe mark ratio) at 25% in the Z coordinate from the image information, and stores the number in the memory 83 (step S34).

Similarly, the controller 80 sets to acquire the probe mark ratio at 50% in the Z coordinate (step S35), and moves the stage 40 to bring the probes 33 into contact with the pads Pd and the overdrive operation is performed (step S36). Then, the controller 80 images the wafer W by the camera 50 (step S37), extracts the number of the probe marks (the probe mark ratio) at 50% in the Z coordinate from the image information, and stores the number in the memory 83 (step S38).

Additionally, the controller 80 sets to acquire the probe mark ratio at 75% in the Z coordinate (step S39), and moves the stage 40 to bring the probes 33 into contact with the pads Pd and the overdrive operation is performed (step S40). Then, the controller 80 images the wafer W by the camera 50 (step S41), extracts the number of the probe marks (the probe mark ratio) at 75% in the Z coordinate from the image information, and stores the number in the memory 83 (step S42).

As described above, the test device 1B can easily acquire the probe mark ratio of each of the Z coordinates in the correction amount calculation process. Then, the controller 80 performs appropriate calculation processing (linear interpolation or the like) based on the Z coordinates and the probe mark ratios, thereby obtaining a function or map information indicating changes in the probe mark ratio when the overdrive operation is performed from the conduction start position to the conduction end position. Further, the controller 80 calculates the correction amount in the three-dimensional direction based on the function or the map information, thereby satisfactorily correcting the movement of the stage 40 in the test process of actually performing the electrical test of the wafer W.

The technical ideas and effects of the present disclosure described in the above embodiments will be described below.

A first aspect of the present invention is the test method of performing the electrical test by bringing the substrate (the wafer W) into contact with multiple probes 33, and includes a step of calculating the correction amount in the three-dimensional direction that is used when the mounting table 45 on which the substrate is mounted is moved in the three-dimensional direction, before the electrical test is performed, and a step of moving the mounting table 45 based on the calculated correction amount in the three-dimensional direction when the electrical test is performed. The step of calculating the correction amount in the three-dimensional direction acquires the information on the contact state in which the multiple probes 33 come into contact with the substrate while the mounting table 45 is raised, and calculates the correction amount in the three-dimensional direction based on the acquired contact state.

According to the above, when the electrical test is performed, the test method can appropriately correct the movement of the mounting table 45 by using the correction amount in the three-dimensional direction calculated before the test. Specifically, the test method uses the information on the contact state when the multiple probes 33 of the probe card 32 attached to the test device 1 come into contact with the substrate. Thus, the correction amount in the three-dimensional direction including the individual differences of the device and the probe card 32, and the type of the substrate can be calculated. Therefore, the test method enables, in the actual electrical test (the test processing), the substrate mounted on the mounting table 45 and the multiple probes 33 to be brought into contact with each other with high accuracy, so that the electrical test can be stably performed.

Additionally, the information on the contact state includes the conduction start position when multiple probes 33 come into contact with the substrate (the wafer W) and start the conduction, and the conduction end position when the conduction between the multiple probes 33 and the substrate is completed after the conduction start position is acquired. As described above, the test method can calculate the correction amount in the three-dimensional direction easily and accurately by using the information on the conduction start position and the conduction end position.

Additionally, the calculating of the correction amount in the three-dimensional direction includes calculating the conduction movement range between the conduction start position and the conduction end position, and calculating the correction amount in the three-dimensional direction based on the conduction movement range. This enables the test method to obtain the correction amount in the three-dimensional direction in the state where the multiple probes 33 are in contact, with high accuracy, by using the conductive movement range.

Additionally, the calculating of the correction amount in the three-dimensional direction includes setting the correction amount in the three-dimensional direction to a greater value as the conduction movement range increases. This enables the test method to bring the substrate (the wafer W) and the multiple probes 33 into contact with each other more stably by moving the mounting table 45 based on the correction amount in the three-dimensional direction.

Additionally, the step of calculating the correction amount in the three-dimensional direction includes setting multiple areas A on the mounting surface 48s of the mounting table 45, the acquiring of the conduction start position includes acquiring the conduction start position for each of the multiple vertices P in the area A that the multiple probes 33 contact among the multiple areas A, the acquiring of the conduction end position includes acquiring the conduction end position for each of the multiple vertices P in the area A that the multiple probes 33 contact among the multiple areas A, and the calculating of the correction amount in the three-dimensional direction includes calculating the correction amount in the three-dimensional direction of the area A that the multiple probes 33 contact based on the conduction start position and the conduction end position for each of the multiple vertices P. This enables the test method to prepare the correction amount in the three-dimensional direction for each of the multiple areas A, and change the correction amount in the three-dimensional direction according to the area A that the multiple probes 33 contact in the actual electrical test. As a result, the 3D contact correction can be performed in more detail according to the contact positions of the multiple probes 33.

Additionally, the angles of the multiple vertices P forming the area A is 150° or less. With this, when the multiple areas A are set, an increase in deviation of the contact positions where the multiple probes 33 contact with the correction amounts in the three-dimensional direction of the respective areas A can be suppressed.

Additionally, the multiple areas A are formed in triangular shapes arranged along the circumferential direction of the mounting table 45 with the center of the mounting table 45 being a base point. As described above, because the multiple areas A are formed along the circumferential direction of the mounting table 45, an appropriate correction amount in each of the areas A arranged in the circumferential direction can be obtained with respect to the load applied to the outer peripheral side of the mounting table 45 from the multiple probes 33.

Additionally, the conduction start position is a position in the vertical direction at the timing when the first probe 33 of the multiple probes 33 conducts. Thus, the test method can easily and surely acquire the conduction start position based on a power change of each of the probes 33.

Additionally, the conduction end position is a position in the vertical direction at the timing when all the multiple probes 33 conduct. Thus, the test method can easily and surely acquire the conduction end position based on the power of each of the probes 33 becoming constant.

Additionally, the information on the contact state is the image information obtained by imaging the probe marks of the multiple pads Pd formed by the contact between the multiple probes 33 and the multiple pads Pd of the substrate (the wafer W). By using the probe marks of the multiple pads Pd in such a way, the test method can recognize in detail the contact state between the probes 33 and the pads Pd during the movement in the Z-axis direction, and can calculate the correction amount in the three-dimensional direction with higher accuracy.

Additionally, the calculating of the correction amount in the three-dimensional direction includes acquiring the index of the number of the probe marks at multiple coordinates in the vertical direction, and calculating the correction amount in the three-dimensional direction based on the index of the number of the probe marks. By using the index of the number of the probe marks at the multiple coordinates in such a way, the test method can easily acquire the contact state between the probes 33 and the pads Pd and calculate the correction amount in the three-dimensional direction.

Additionally, a second aspect of the present disclosure is the correction amount calculation method of correcting the movement amount of the mounting table 45 on which the substrate is mounted in three-dimensional direction when the electrical test is performed by bringing the substrate (the wafer W) into contact with the multiple probes 33, acquires the information on the contact state in which the multiple probes 33 are in contact with the substrate while the mounting table 45 is raised, and calculates the correction amount in three-dimensional direction based on the acquired information on the contact state.

Additionally, a third aspect of the present disclosure is the test device 1 that performs the electric test on the substrate (the wafer W), and includes multiple probes 33 configured to contact the substrate to perform the electric test, the mounting table 45 on which the substrate is mounted, and the controller (the main controller 81) configured to control the operation of the mounting table 45. The controller performs a process of calculating the correction amount in the three-dimensional direction that is used when the mounting table 45 is moved in the three-dimensional direction, before the electrical test is performed and a process of moving the mounting table 45 based on the calculated correction amount in the three-dimensional direction when the electrical test is performed. The process of calculating the correction amount in the three-dimensional direction includes acquiring the information on the contact state in which the multiple probes 33 are in contact with the substrate while the mounting table 45 is raised, and calculating the correction amount in the three-dimensional direction based on the acquired information on the contact state.

In the second and third aspects described above, the probes and the substrate can be brought into contact with each other with high accuracy by obtaining the correction amount including the individual differences of the device, the probe card, and the substrate.

The test method, the correction amount calculation method, and the test device 1 according to the embodiments disclosed herein are illustrative and non-restrictive in all respects. The embodiments can be modified and improved in various forms without departing from the scope and spirit of the appended claims. The matters described in the above multiple embodiments can also take other configurations to the extent that they are not contradictory, and can be combined to the extent that they are not contradictory.

This application claims priority to Japanese Patent Application No. 2021-199314 filed on Dec. 8, 2021, and Japanese Patent Application No. 2022-124206 filed on Aug. 3, 2022, the entire contents of which are incorporated herein by reference.

### Description of Reference Symbols

1 test device
33 probe
45 mounting table
81 main controller
W wafer

1. A test method of performing an electrical test by bringing a substrate into contact with a plurality of probes, the test method comprising:
calculating a correction amount in a three-dimensional direction that is used when a mounting table on which a substrate is mounted is moved in the three-dimensional direction, before the electrical test is performed; and
moving the mounting table based on the calculated correction amount in the three-dimensional direction when the electrical test is performed,
wherein the calculating of the correction amount in the three-dimensional direction includes:
acquiring information on a contact state in which the plurality of probes are in contact with the substrate while the mounting table is raised: and
calculating the correction amount in the three-dimensional direction based on the acquired information on the contact state.

2. The test method as claimed in claim 1, wherein the information on the contact state includes:
a conduction start position at which the plurality of probes are in contact with the substrate to start conduction; and
a conduction end position at which conduction between the plurality of probes and the substrate is completed after the conduction start position is acquired.

3. The test method as claimed in claim 2, wherein the calculating of the correction amount in the three-dimensional direction includes calculating a conduction movement range between the conduction start position and the conduction end position, and calculating the correction amount in the three-dimensional direction based on the conduction movement range.

4. The test method as claimed in claim 3, wherein the calculating of the correction amount in the three-dimensional direction includes setting the correction amount in the three-dimensional direction to a greater value as the conduction movement range increases.

5. The test method claimed in claim 2,
wherein the calculating of the correction amount in the three-dimensional direction includes setting a plurality of areas on a mounting surface of the mounting table;
wherein the acquiring of the conduction start position includes acquiring the conduction start position for each of a plurality of vertices in an area where the plurality of probes are in contact among the plurality of areas,
wherein the acquiring of the conduction end position includes acquiring the conduction end position for each of the plurality of vertices in the area where the plurality of probes are in contact among the plurality of areas, and
wherein the calculating of the correction amount in the three-dimensional direction includes calculating the correction amount of the area where the plurality of probes contact in the three-dimensional direction, based on the conduction start position and the conduction end position for each of the plurality of vertices.

6. The test method as claimed in claim 5, wherein angles of the plurality of vertices forming the area are 150° or less.

7. The test method as claimed in claim 5, wherein the plurality of areas are formed in triangular shapes arranged along a circumferential direction of the mounting table with a center of the mounting table being a base point.

8. The test method as claimed in claim 2, wherein the conduction start position is a position in a vertical direction at a timing when a first probe among the plurality of probes conducts.

9. The test method as claimed in claim 2, wherein the conduction end position is a position in a vertical direction at a timing when all the plurality of probes conduct.

10. The test method as claimed in claim 1, wherein the information on the contact state includes image information obtained by imaging probe marks of a plurality of pads formed by contacts between the plurality of probes and the plurality of pads of the substrate.

11. The test method as claimed in claim 10, wherein the calculating of the correction amount in the three-dimensional direction includes acquiring an index of a number of the probe marks at a plurality of coordinates in a vertical direction, and calculating the correction amount in the three-dimensional direction based on the index of the number of the probe marks.

12. A correction amount calculation method of correcting a movement amount of a mounting table on which a substrate is mounted in a three-dimensional direction when an electrical test is performed by bringing the substrate into contact with a plurality of probes, the correction amount calculation method comprising:
acquiring information on a contact state in which the plurality of probes are in contact with the substrate while the mounting table is raised; and
calculating a correction amount in the three-dimensional direction based on the acquired information on the contact state.

13. A test device of performing an electrical test of a substrate, the test device comprising:
a plurality of probes configured to perform the electrical test upon contact with the substrate;
a mounting table configured to mount the substrate; and
a controller configured to control an operation of the mounting table,
wherein the controller performs:
a process of calculating a correction amount in a three-dimensional direction that is used when the mounting table is moved in the three-dimensional direction, before the electrical test is performed; and
a process of moving the mounting stage based on the calculated correction amount in the three-dimensional direction when the electrical test is performed, and
wherein the process of calculating the correction amount in the three-dimensional direction includes:
acquiring information on a contact state in which the plurality of probes are in contact with the substrate while the stage is raised; and
calculating the correction amount in the three-dimensional direction based on the acquired information on the contact state.
